(19) United States
(12) Patent Application Publication
(10) Pub. No.: US 2025/0385215 A1
(43) Pub. Date: Dec. 18, 2025

(54) HYBRID BONDING APPARATUS

(71) Applicant: SAMSUNG ELECTRONICS CO., LTD., Suwon-si (KR)

(72) Inventors: Seung Ho HAHN, Suwon-si (KR); Sung-Yeol KIM, Suwon-si (KR); Min Woo RHEE, Suwon-si (KR); Bum Ki MOON, Suwon-si (KR); Jung Shin LEE, Suwon-si (KR); Kyeong Bin LIM, Suwon-si (KR); Sung Ho JANG, Suwon-si (KR)

(73) Assignee: SAMSUNG ELECTRONICS CO., LTD., Suwon-si (KR)

(21) Appl. No.: 19/092,805

(22) Filed: Mar. 27, 2025

(30) Foreign Application Priority Data
Jun. 18, 2024 (KR) 10-2024-0079225

(51) Int. Cl. H01L 23/00; H01J 37/32; H01L 21/67; H01L 21/677

(52) U.S. Cl. CPC H01L 24/74; H01J 37/32146; H01J 37/32155; H01L 21/6715; H01L 21/67739; H01J 2237/332; H01L 24/80; H01L 2224/74; H01L 2224/8002; H01L 2224/80895; H01L 2224/80896

(57) ABSTRACT

A hybrid bonding apparatus that is able to reduce metal contamination is provided. The hybrid bonding apparatus may include a plasma treater configured to perform a pulsed plasma surface treatment on a first wafer, wherein the first wafer includes a bonding pad; a pulse controller connected to the plasma treater and configured to control on/off of a pulse of the pulsed plasma surface treatment; a cleaner configured to clean the first wafer; a bonder configured to bond the first wafer and a second wafer to each other; and an equipment front end module (EFEM) configured to load the first wafer and the second wafer, and unload the first wafer and the second wafer, after being bonded together.

### CROSS-REFERENCE TO RELATED APPLICATION

This application claims priority from Korean Patent Application No. 10-2024-0079225, filed on Jun. 18, 2024, in the Korean Intellectual Property Office, and all the benefits accruing therefrom under 35 U.S.C. 119, the contents of which in its entirety are herein incorporated by reference.

### BACKGROUND

### 1. Field

Embodiments of the present disclosure relate to a hybrid bonding apparatus.

### 2. Description of Related Art

As a semiconductor device become highly integrated, a scheme for stacking wafers in a three-dimensional manner is being researched. In a hybrid bonding scheme, two layers (wafers, etc.), each including a dielectric layer made of an oxide and a metal wiring such as copper embedded therein, may be directly bonded to each other to form an interconnection between the metal wirings and to integrate the two dielectric layers with each other to form a permanent bond therebetween. The hybrid bonding is known as Direct Bond Interconnect (DBI). The hybrid bonding allows the wafers to be directly connected to each other in a face-to-face manner via adhesion between the embedded metal wirings and fusion between the dielectric layers at a bonding interface.

### SUMMARY

According to embodiments of the present disclosure, a hybrid bonding apparatus that is able to reduce metal contamination is provided.

Aspects of embodiments of the present disclosure are not limited to the above-mentioned aspects. Other aspects and advantages of embodiment of the present disclosure that are not mentioned may be understood based on following descriptions, and may be more clearly understood based on example embodiments of the present disclosure. Further, it will be easily understood that aspects and advantages of embodiments of the present disclosure may be realized using means described in the present disclosure and combinations thereof.

According to embodiments of the present disclosure, a hybrid bonding apparatus may be provided and include: a plasma treater configured to perform a pulsed plasma surface treatment on a first wafer, wherein the first wafer includes a bonding pad; a pulse controller connected to the plasma treater and configured to control on/off of a pulse of the pulsed plasma surface treatment; a cleaner configured to clean the first wafer; a bonder configured to bond the first wafer and a second wafer to each other; and an equipment front end module (EFEM) configured to load the first wafer and the second wafer, and unload the first wafer and the second wafer, after being bonded together.

According to embodiments of the present disclosure, a hybrid bonding apparatus may be provided and include: a plasma treater configured to perform a pulsed plasma surface treatment on a wafer, wherein the wafer includes first bonding pads; a pulse controller connected to the plasma treater and configured to control on/off of a pulse of the pulsed plasma surface treatment; a cleaner configured to clean the wafer; a bonder configured to bond the wafer and a plurality of dies to each other, wherein the plurality of dies include third bonding pads, respectively; and an equipment front end module (EFEM) configured to load or unload the wafer and the plurality of dies that are bonded to each other, wherein the bonder is further configured to bond the plurality of dies onto the wafer such that the third bonding pads are connected to the first bonding pads.

According to embodiments of the present disclosure, a method may be provided and include: loading a first wafer into an equipment front end module (EFEM) of a hybrid bonding apparatus and then transferring the first wafer from the EFEM to a plasma treater of the hybrid bonding apparatus; loading one from among a second wafer and a plurality of dies into the EFEM and then transferring the one from among the second wafer and the plurality of dies from the EFEM to the plasma treater; performing a pulsed plasma surface treatment on the first wafer by the plasma treater and a pulse controller of the hybrid bonding apparatus, and then transferring the first wafer to a cleaner of the hybrid bonding apparatus, wherein the pulse controller is connected to the plasma treater and configured to control on/off of a pulse of the pulsed plasma surface treatment; performing the pulsed plasma surface treatment on the one from among the second wafer and the plurality of dies by the plasma treater and the pulse controller, and then transferring the one from among the second wafer and the plurality of dies to the cleaner; cleaning the first wafer by the cleaner of the hybrid bonding apparatus, and then transferring the first wafer to a bonder of the hybrid bonding apparatus; cleaning, the one from among the second wafer and the plurality of dies by the cleaner, and then transferring the one from among the second wafer and the plurality of dies to the bonder; bonding the first wafer and the one from among the second wafer and the plurality of dies to each other by the bonder, and then transferring the first wafer and the one from among the second wafer and the plurality of dies, that are bonded together, to the EFEM; and unloading, from the EFEM, the first wafer and the one from among the second wafer and the plurality of dies that are bonded to each other.

The specific details of other example embodiments are included in the detailed description and drawings.

### BRIEF DESCRIPTION OF DRAWINGS

The above and other aspects and features of embodiments of the present disclosure will become more apparent by describing in detail example embodiments thereof with reference to the attached drawings, in which:

FIG. 1 and FIG. 2 are diagrams for illustrating a hybrid bonding apparatus according to some embodiments of the present disclosure.

FIGS. 3 to 6 are diagrams for illustrating hybrid bonding using a hybrid

bonding apparatus according to some embodiments of the present disclosure.

FIG. 7 is a cross-sectional view cut along a line A-A in FIG. 6.

FIG. 8 is a diagram for illustrating hybrid bonding using a hybrid bonding apparatus according to some embodiments of the present disclosure.

FIG. 9 is a cross-sectional view cut along a line B-B in FIG. 8.

FIG. 10 is a diagram for illustrating the plasma treater as shown in FIG. 1 and FIG. 2.

FIG. 11 is an enlarged view of a portion P of FIG. 10.

FIG. 12 is a diagram showing a plasma shape in FIG. 10.

FIG. 13 is a diagram for illustrating a plasma ion energy distribution of the plasma treater in FIG. 10.

FIG. 14 is a diagram for illustrating a period S1 in FIG. 12.

FIG. 15 is a diagram for illustrating a period S2 in FIG. 12.

FIG. 16 is a diagram for illustrating a period S3 in FIG. 12.

FIGS. 17 to 20 are diagrams for illustrating how a pulse controller in FIG. 10 controls source radio-frequency (RF) power and bias RF power.

FIG. 21 is a diagram for illustrating a hybrid bonding method according to some embodiments of the present disclosure.

### DETAILED DESCRIPTION

Although terms such as “first,” “second,” “upper,” and “lower” are used herein to describe various elements or components, these element or components are not limited by the terms. Rather, the terms are merely used herein to distinguish one element or component from another element or component. Therefore, a first element or component as mentioned below may also be a second element or component within the technical spirit of the present disclosure. Further, a lower element or component as mentioned below may also be an upper element or component within the technical spirit of the present disclosure.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

Hereinafter, non-limiting example embodiments of the present disclosure are described in detail with reference to the attached drawings. The same reference numerals are used for the same components in the drawings, and duplicate descriptions thereof may be omitted.

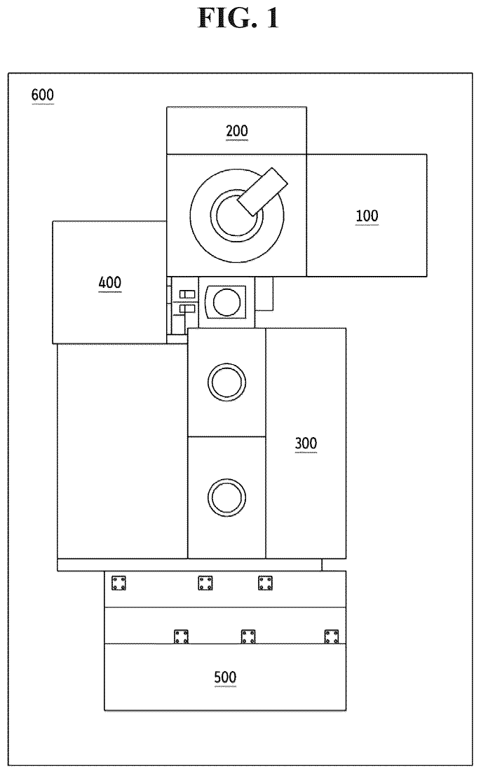

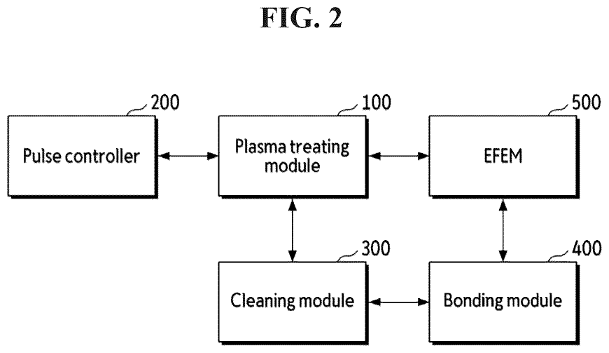

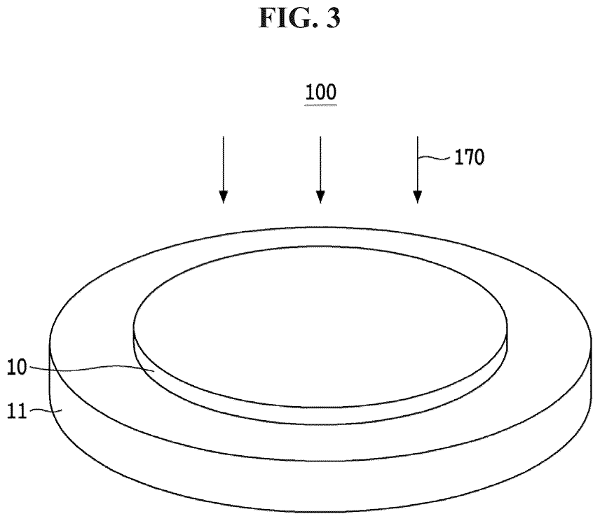

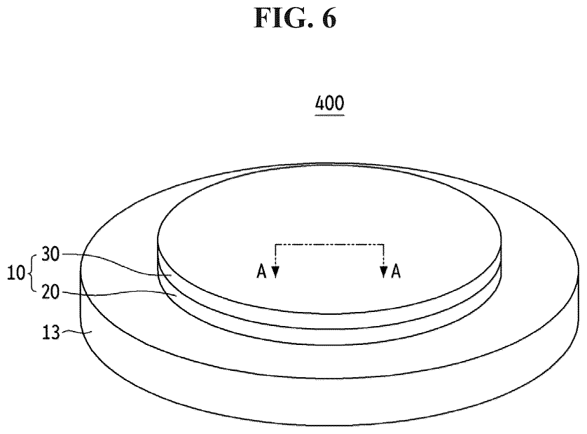

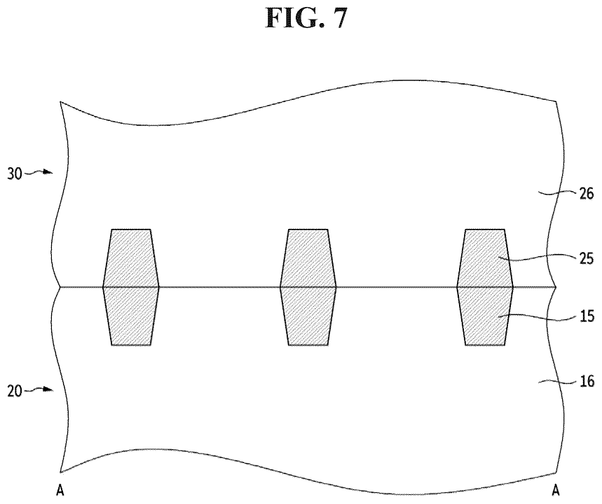

Hereinafter, with reference to FIGS. 1 to 7, a hybrid bonding apparatus according to some embodiments of the present disclosure is described. FIG. 1 and FIG. 2 are diagrams for illustrating a hybrid bonding apparatus according to some embodiments of the present disclosure. FIGS. 3 to 6 are diagrams for illustrating hybrid bonding using a hybrid bonding apparatus according to some embodiments of the present disclosure. FIG. 7 is a cross-sectional view cut along a line A-A in FIG. 6.

Referring to FIGS. 1 to 7, the hybrid bonding apparatus according to some embodiments of the present disclosure may include a plasma treater 100 (e.g., a plasma treating module), a pulse controller 200, a cleaner 300 (e.g., a cleaning module), a bonder 400 (e.g., a bonding module), and an equipment front end module (EFEM) 500.

The hybrid bonding apparatus may be disposed in a clean room 600. For example, the plasma treater 100, the pulse controller 200, the cleaner 300, the bonder 400, and the EFEM 500 may be disposed in the clean room 600.

In some embodiments, the clean room 600 may be embodied as a rectangular parallelepiped room with an inner space defined therein, and may have a space shielded from fine dust and foreign substances to maintain a cleanliness level within a preset range.

The EFEM 500 may load or unload the wafer therein or out thereof. The EFEM 500 may be a space where the wafer is temporarily stored. The wafer loaded in the EFEM 500 may be transferred to the plasma treater 100, the cleaner 300, or the bonder 400 using a transfer module. Alternatively, the wafer that has been subjected to the hybrid bonding process through the plasma treater 100, the cleaner 300, and the bonder 400 may be transferred to the EFEM 500 using the transfer module and may be unloaded from the EFEM 500 to an outside.

The plasma treater 100 may perform plasma surface treatment on a wafer. The wafer loaded in the EFEM 500 may be transferred to the plasma treater 100 using the transfer module. The wafer transferred to the plasma treater 100 may be subjected to plasma surface treatment in the plasma treater 100.

For example, FIG. 3 is a diagram briefly showing a process in the plasma treater 100. A wafer 10 may be placed on a first wafer stage 11. The plasma treater 100 may perform pulsed plasma surface treatment 170 on the wafer 10.

The pulse controller 200 may be connected to the plasma treater 100. The pulse controller 200 may control a shape of the plasma by controlling the plasma treater 100. In other words, the pulse controller 200 may control the shape of plasma by controlling on/off of the pulse. For example, the pulse controller 200 may control the plasma treater 100 to apply pulsed plasma to the wafer 10. Detailed description about the plasma treater 100 and the pulse controller 200 will be set forth in detail later.

The cleaner 300 may clean the wafer 10.

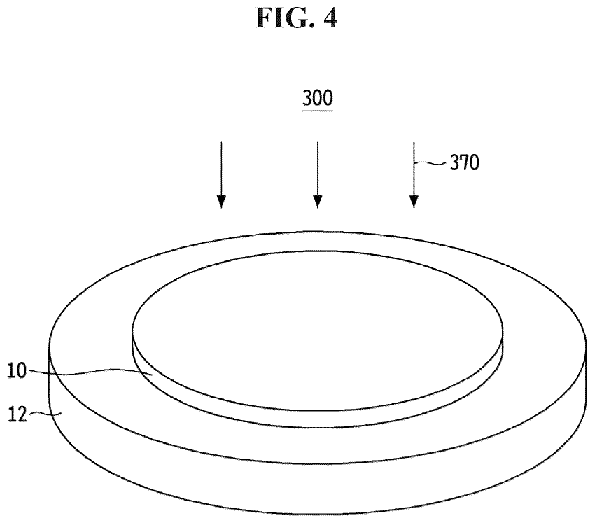

For example, FIG. 4 is a diagram briefly showing the process in the cleaner 300. The wafer 10 on which pulsed plasma surface treatment 170 has been completed may be transferred to the cleaner 300 by the transfer module. The wafer 10 may be placed on a second wafer stage 12. The cleaner 300 may perform a cleaning process 370 on the wafer 10. The cleaner 300 may coat the surface of the wafer 10 with deionized (DI) water using a spin coater. The DI water not only cleans the surface of the wafer, but also allows hydroxyl (—OH) groups to be well bonded to the surface of the wafer substrate to make the hybrid bonding easier.

The bonder 400 may align the wafers (e.g., a first wafer 20 and a second wafer 30) with each other and bond together the wafers (e.g., the first wafer 20 and the second wafer 30). According to embodiments, an annealing process may be performed on the wafer 10 on which the bonding process has been completed using a separate apparatus.

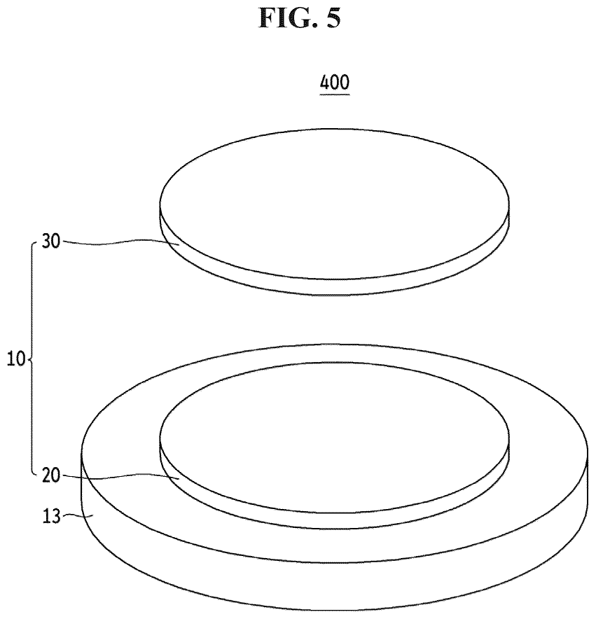

FIG. 5 and FIG. 6 are diagrams that briefly show the process in the bonder 400. Wafers (e.g., the first wafer 20 and the second wafer 30) on which the cleaning process 370 has been completed may be transferred to the bonder 400 using the transfer module. The first wafer 20 may be placed on a third wafer stage 13. In FIG. 5, the second wafer 30 may be aligned with the first wafer 20. In FIG. 6, the second wafer 30 may be bonded onto the first wafer 20.

Referring to FIG. 7, the first wafer 20 may include a first insulating film 16 and a first bonding pad 15 embedded in the first insulating film 16. The second wafer 30 may include a second insulating film 26 and a second bonding pad 25 embedded in the second insulating film 26.

The first wafer 20 and the second wafer 30 may be bonded to each other by the bonder 400. The first bonding pad 15 may be bonded to the second bonding pad 25. The first insulating film 16 and the second insulating film 26 may be bonded to each other. According to embodiments, the first bonding pad 15 may overlap with the second bonding pad 25 and the second insulating film 26 in a vertical direction. That is, the first bonding pad 15 may be bonded to the second bonding pad 25 and the second insulating film 26 in the vertical direction. Likewise, the second bonding pad 25 may overlap with the first bonding pad 15 and the first insulating film 16 in the vertical direction. That is, the second bonding pad 25 may be bonded to the first bonding pad 15 and the first insulating film 16 in the vertical direction.

Each of a width of the first bonding pad 15 and a width of the second bonding pad 25 may become smaller as each of the first bonding pad 15 and the second bonding pad 25 extends away from a boundary between the first wafer 20 and the second wafer 30.

According to embodiments, in a plan view, each of the first bonding pad 15 and the second bonding pad 25 may have various shapes, such as a square shape, a diamond shape, a circular shape, an oval shape, or a hexagon shape.

Each of the first bonding pad 15 and the second bonding pad 25 may include a conductive material including metal. Each of the first bonding pad 15 and the second bonding pad 25 may include at least one from among copper (Cu), aluminum (Al), tungsten (W), ruthenium (Ru), and molybdenum (Mo). When each of the first bonding pad 15 and the second bonding pad 25 are made of copper (Cu), a bonding scheme between the first wafer 20 and the second wafer 30 may be a Cu-Cu bonding scheme.

The first insulating film 16 and the second insulating film 26 may cover the first bonding pad 15 and the second bonding pad 25, respectively. Each of the first insulating film 16 and the second insulating film 26 may include an insulating material. Each of the first insulating film 16 and the second insulating film 26 may include, for example, at least one from among silicon oxide, silicon oxynitride, and a low-k material with a dielectric constant lower than a dielectric constant of silicon oxide. However, embodiments of the present disclosure are not limited thereto.

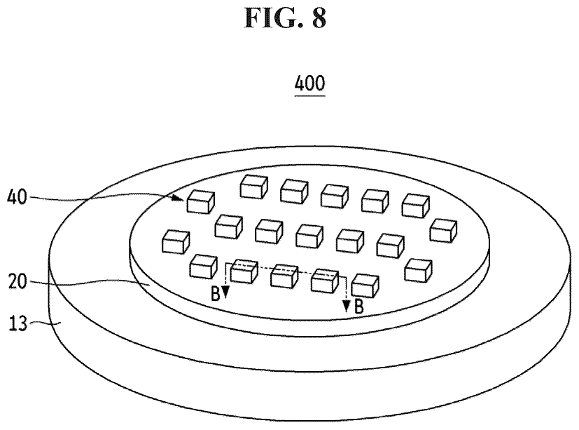

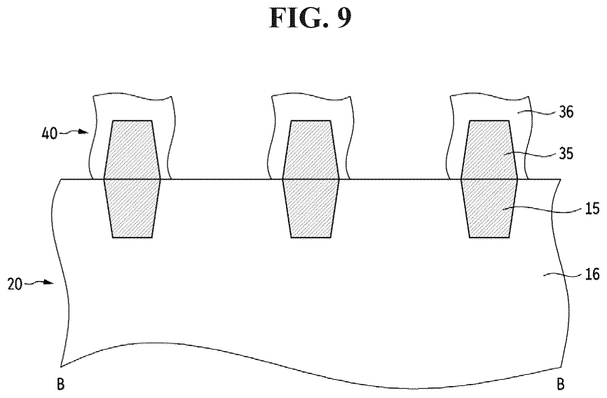

FIG. 8 is a diagram for illustrating hybrid bonding using a hybrid bonding apparatus according to some embodiments of the present disclosure. FIG. 9 is a cross-sectional view cut along a line B-B in FIG. 8. For convenience of description, contents duplicate with contents described above with reference to FIGS. 1 to 7 may be briefly described or repeated descriptions thereof may be omitted.

Referring to FIG. 8 and FIG. 9, a plurality of dies 40 may be disposed on the first wafer 20. The first wafer 20 and the plurality of dies 40 may be bonded to each other. The first wafer 20 and the plurality of dies 40 may be transferred to the bonder 400 through the plasma treater 100 and the cleaner 300.

The first wafer 20 may include the first insulating film 16 and a plurality of first bonding pads 15 embedded in the first insulating film 16. Each of the plurality of dies 40 may include a third bonding pad 35 and a third insulating film 36 covering the third bonding pad 35. The third bonding pads 35 may be disposed on the first bonding pads 15, respectively. The third bonding pads 35 and the first bonding pads 15 may be bonded to each other, respectively. The third insulating film 36 may be bonded to the first insulating film 16. According to embodiments, the first bonding pad 15 may overlap with the third bonding pad 35 and the third insulating film 36.

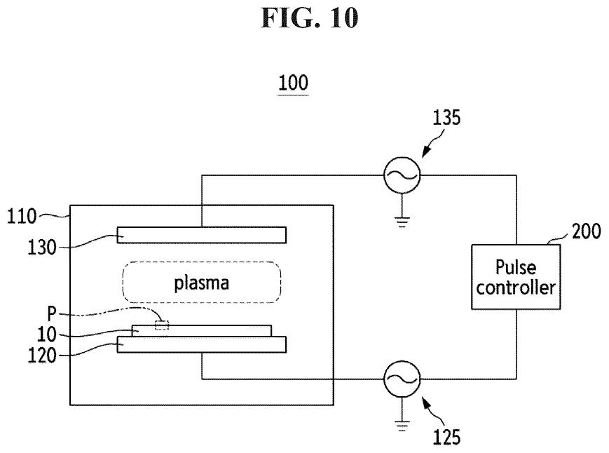

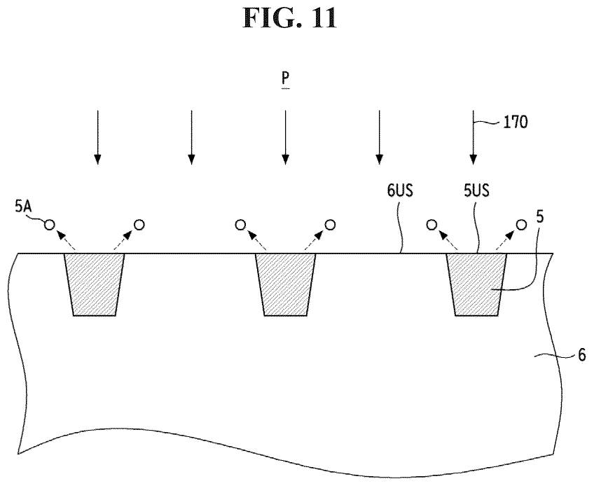

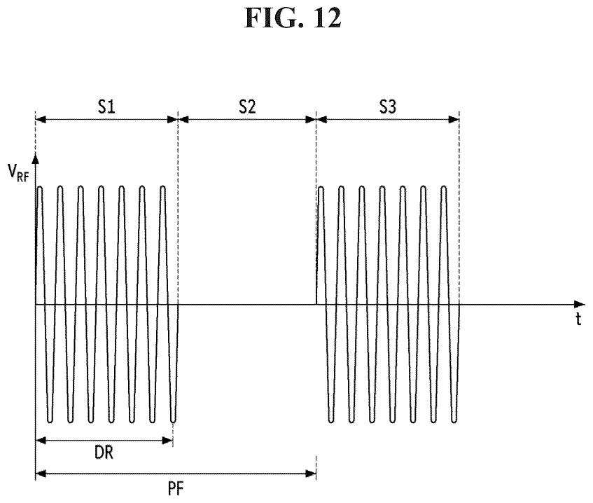

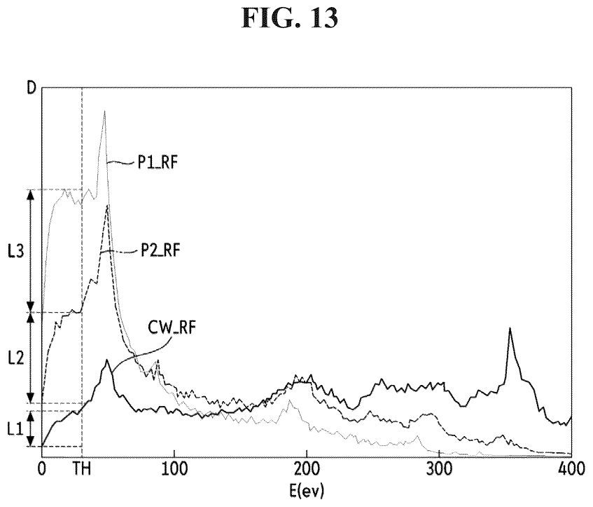

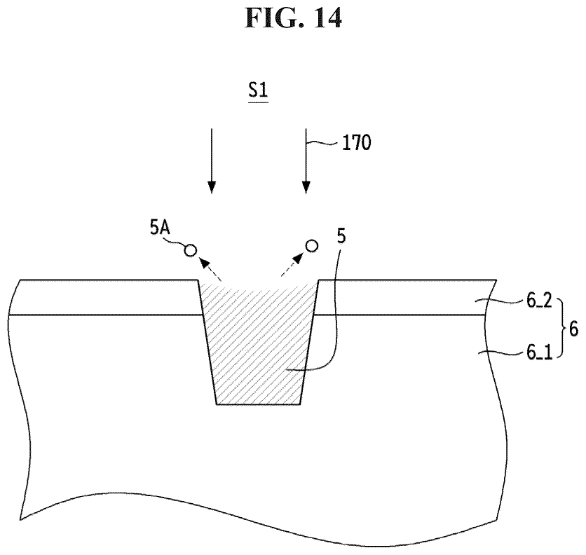

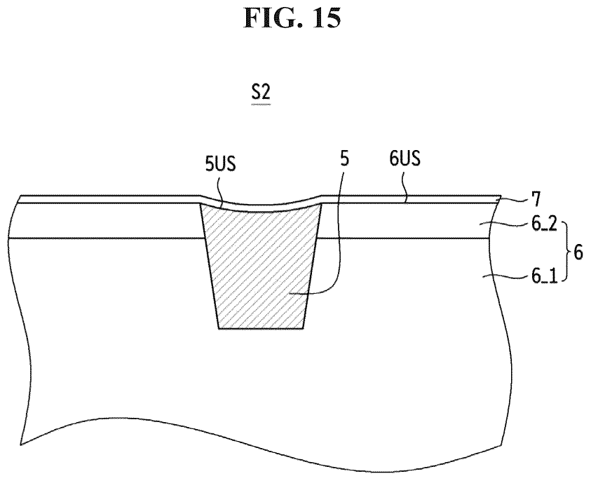

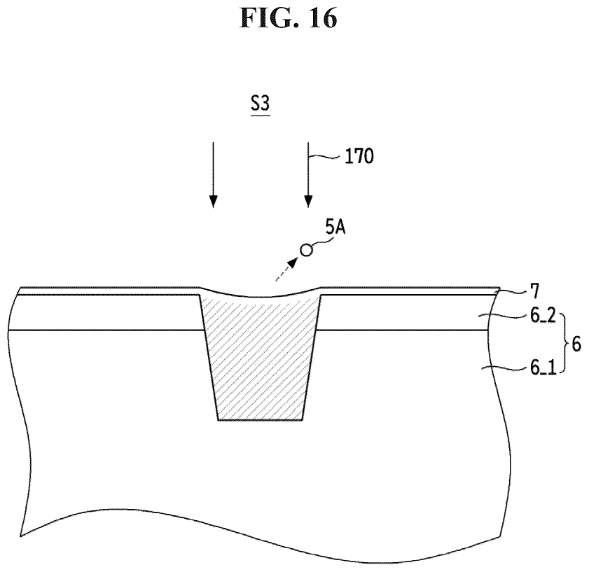

FIG. 10 is a diagram for illustrating the plasma treater as shown in FIG. 1 and FIG. 2. FIG. 11 is an enlarged view of a portion P of FIG. 10. FIG. 12 is a diagram showing a plasma shape in FIG. 10. FIG. 13 is a diagram for illustrating a plasma ion energy distribution of the plasma treater in FIG. 10. FIG. 14 is a diagram for illustrating a period S1 in FIG. 12. FIG. 15 is a diagram for illustrating a period S2 in FIG. 12. FIG. 16 is a diagram for illustrating a period S3 in FIG. 12. For convenience of description, contents duplicate with contents described above with reference to FIGS. 1 to 9 may be briefly described or repeated descriptions thereof may be omitted.

Referring to FIG. 10 and FIG. 11, the plasma treater 100 includes a process chamber 110, a bias electrode 120, a source electrode 130, a bias radio-frequency (RF) power 125, and a source RF power 135. The plasma treater 100 may be connected to the pulse controller 200.

The process chamber 110 may provide a closed space in which a plasma surface treating process is performed on the wafer 10. The process chamber 110 may be a cylindrical vacuum chamber. The process chamber 110 may be made of metal such as aluminum and stainless steel. According to embodiments, a gate through which the wafer 10 is input into or output out of the process chamber 110 may be installed at one side of the process chamber 110. The wafer 10 may be loaded or unloaded into or from the plasma treater 100 through the gate.

The source electrode 130 and the bias electrode 120 may generate plasma within the process chamber 110. The bias electrode 120 may be disposed at a lower portion of the space defined by the process chamber 110. The wafer 10 may be placed on the bias electrode 120. The source electrode 130 may be disposed at an upper portion of the space defined by the process chamber 110. The source electrode 130 may be disposed above the bias electrode 120.

The source electrode 130 may be connected to the source RF power 135. The bias electrode 120 may be connected to the bias RF power 125. The source electrode 130 may receive an RF source voltage output from the source RF power 135. The bias electrode 120 may receive an RF bias voltage output from the bias RF power 125.

The source RF power 135 and the bias RF power 125 may be connected to the pulse controller 200. The pulse controller 200 may control the source RF power 135 to control on/off of the source. The pulse controller 200 may control the bias RF power 125 to control on/off of the bias. The pulse controller 200 may adjust the source RF power 135 and the bias RF power 125 to control the plasma treater 100 to generate pulsed plasma within the process chamber 110.

The wafer 10 may be subjected to the pulsed plasma surface treatment 170 in the plasma treatment module 100. The pulsed plasma surface treatment 170 may be performed on an upper surface 5US of bonding pads 5 and an upper surface 6US of an insulating film 6. When the plasma surface treatment is performed on the wafer 10, metal particles 5A of the bonding pads 5 may bounce toward the insulating film 6 due to ion bombardment, thereby causing metal re-sputtering. According to comparative embodiments, when continuous wave (CW) plasma surface treatment is performed on the wafer 10, it is difficult to control the behavior of ions, thereby causing metal re-sputtering. When the metal re-sputtering occurs, the metal particles 5A may bounce onto the insulating film 6, thereby causing metal contamination. When the metal contamination into the insulating film 6 occurs, the hybrid bonding characteristics between the wafers or between the wafer and the die may be reduced. However, when the pulsed plasma surface treatment 170 is performed on the wafer 10, the ion bombardment that causes the metal re-sputtering may be minimized by controlling on/off of the pulse.

Referring to FIG. 12, the plasma in the pulsed plasma surface treatment 170 may be pulsed plasma. In FIG. 12, a horizontal axis t represents a time, and a vertical axis VRF represents RF voltage.

The pulse controller 200 may change the ion energy distribution of the plasma by adjusting a pulse frequency PF and a duty ratio DR of the pulsed plasma.

For example, FIG. 13 shows ion energy distribution D based on ion energy E in each of first pulsed plasma P1_RF, second pulsed plasma P2_RF, and CW plasma CW_RF. The first pulsed plasma P1_RF may have a lower duty ratio than a duty ratio of the second pulsed plasma P2_RF. A horizontal axis of FIG. 13 denotes the ion energy E (eV), and a vertical axis of FIG. 13 denotes the ion energy distribution D of the plasma.

Referring to FIG. 13, the ion energy distribution based on a metal re-sputtering threshold energy TH may be identified. When the plasma ion energy is equal to or greater than the metal re-sputtering threshold energy TH, the metal re-sputtering may occur. When the plasma ion energy is lower than the metal re-sputtering threshold energy TH, each of the ion energy distribution L3 of the first pulsed plasma P1_RF and the ion energy distribution L2 of the second pulsed plasma P2_RF is greater than the ion energy distribution L1 of the CW plasma CW_RF. That is, compared to the CW plasma CW_RF, each of the first pulsed plasma P1_RF and the second pulsed plasma P2_RF has a wider energy region in which the plasma ion energy is lower than the metal re-sputtering threshold energy TH. Further, the maximum ion energy of each of the first pulsed plasma P1_RF and the second pulsed plasma P2_RF is lower than the maximum ion energy of the CW plasma CW_RF. That is, the pulse controller 200 may control the on/off of the pulse to adjust the maximum energy of the plasma ions and the ion energy distribution. Accordingly, ion bombardment that causes the metal re-sputtering may be minimized such that the hybrid bonding characteristics may be improved.

Referring again to FIG. 12, the pulse controller 200 may control on/off of the pulse. For example, a first period S1 is the pulse-on period, a second period S2 is a pulse-off period and the third period S3 is a pulse-on period. FIGS. 14 to 16 are diagrams showing pulsed plasma surface treatment 170 performed on the wafer 10 in the first period S1, the second period S2, and the third period S3, respectively.

Referring to FIG. 12 and FIG. 14, the insulating film 6 may be divided into a first portion 6_1 and a second portion 6_2 by the pulsed plasma surface treatment 170. The second portion 6_2 may be an area activated by the pulsed plasma surface treatment 170. The first portion 6_1 may be an area unaffected by the pulsed plasma surface treatment 170. When the pulsed plasma surface treatment 170 is performed on the insulating film 6, the second portion 6_2 containing OH groups may be formed in the surface of the insulating film 6. The second portion 6_2 may be an area where the surface of the insulating film 6 is activated. When the surface of the insulating film 6 is activated, the bonding characteristics between the first insulating film 16 (see FIG. 7) and the second insulating film 26 (see FIG. 7) may be improved in the hybrid bonding. The ion bombardment may occur due to the pulsed plasma surface treatment 170. The metal re-sputtering may occur in which the metal particles 5A contained in the bonding pad 5 bounce onto the insulating film 6 due to the ion bombardment.

Referring to FIG. 12 and FIG. 15, a passivation film 7 may be disposed on the insulating film 6. The second period S2 is a pulse-off period, in which no plasma surface treatment is performed on the wafer 10. The passivation film 7 may be formed on the insulating film 6 by highly reactive radicals. The passivation film 7 may extend along the upper surface 6US of the insulating film 6 and the upper surface 5US of the bonding pad 5.

Referring to FIG. 12 and FIG. 16, the pulsed plasma surface treatment 170 may be performed again on the wafer 10. The passivation film 7 may serve to reduce the effect of ion bombardment in the third period S3. That is, the passivation film 7 formed in the pulse-off period may prevent the insulating film 6 from being contaminated with the metal re-sputtering.

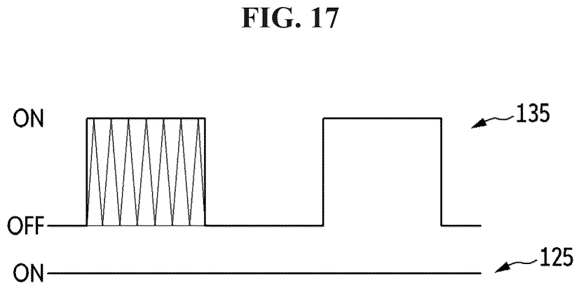

FIGS. 17 to 20 are diagrams for illustrating how the pulse controller in FIG. 10 controls source RF power and bias RF power. For convenience of description, contents duplicate with contend described above with reference to FIGS. 1 to 16 may be briefly described or repeated descriptions thereof may be omitted.

Referring to FIG. 10 and FIG. 17 to FIG. 20, the pulse controller 200 may control on/off of the pulse. Controlling the on/off of the pulse by the pulse controller 200 may include controlling on/off of each of the source RF power 135 and the bias RF power 125 by the pulse controller 200. The pulse controller 200 may control the source RF power 135 to apply a continuous wave (CW) or a pulse to the source electrode 130. The pulse controller 200 may control the bias RF power 125 to apply a continuous wave or a pulse to the bias electrode 120.

Referring to FIG. 17, in the pulsed plasma surface treatment 170, the pulsed plasma may be source pulsing. In this case, the bias RF power 125 may be continuous wave (CW). That is, the bias voltage may be kept in an on state. A pulse may be applied to the source RF power 135. That is, turned-on and off of the source voltage may be periodically repeated.

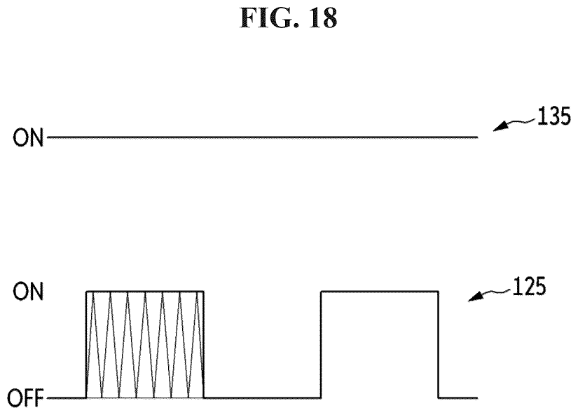

Referring to FIG. 18, in the pulsed plasma surface treatment 170, the pulsed plasma may be bias pulsing. In this case, a pulse may be applied to the bias RF power 125. That is, turned-on and off of the bias voltage may be periodically repeated. The source RF power 135 may be a continuous wave. That is, the source voltage may be kept in an on state.

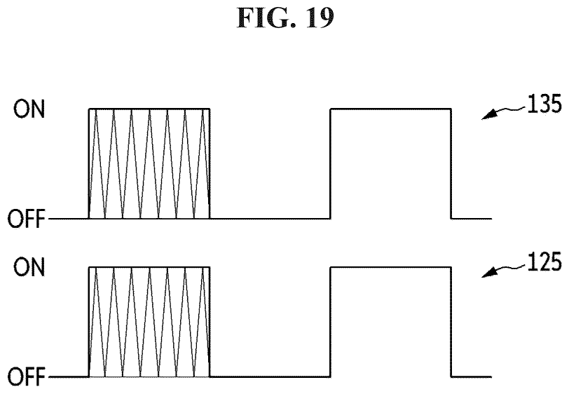

Referring to FIG. 19, in the pulsed plasma surface treatment 170, the pulsed plasma may be synchronous pulsing. In this case, a pulse may be applied to each of the bias RF power 125 and the source RF power 135. That is, turned-on/off of the bias voltage and turned-on/off of the source voltage may be periodically repeated. In the synchronous pulsing, a difference between a phase of the bias pulse and a phase of the source pulse may be absent.

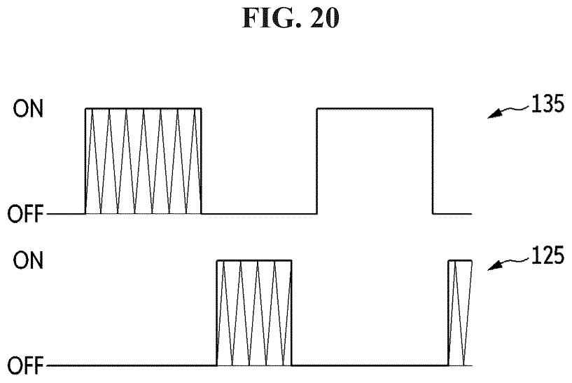

Referring to FIG. 20, in the pulsed plasma surface treatment 170, the pulsed plasma may be asynchronous pulsing. In this case, a pulse may be applied to each of the bias RF power 125 and the source RF power 135. That is, turned-on/off of the bias voltage and turned-on/off of the source voltage may be periodically repeated. In the asynchronous pulsing, a difference between a phase of the bias pulse and a phase of the source pulse may occur.

As shown in FIGS. 17 to 20, when the pulsed plasma surface treatment 170 is performed on the wafer 10, a pulse mode may vary. The pulse controller 200 controls the source RF power 135 and the bias RF power 125 to enable various pulse modes. With reference to FIGS. 17 to 20, the pulse mode may be performed in the source pulsing, bias pulsing, synchronous pulsing, and asynchronous pulsing manner. However, embodiments of the present disclosure are not limited thereto. The pulse controller 200 may provide various pulse modes by adjusting a period and a phase of the source pulsing or a period and a phase of the bias pulsing. Due to the various pulse modes, the ion energy distribution of the plasma may be controlled in the pulsed plasma surface treatment 170.

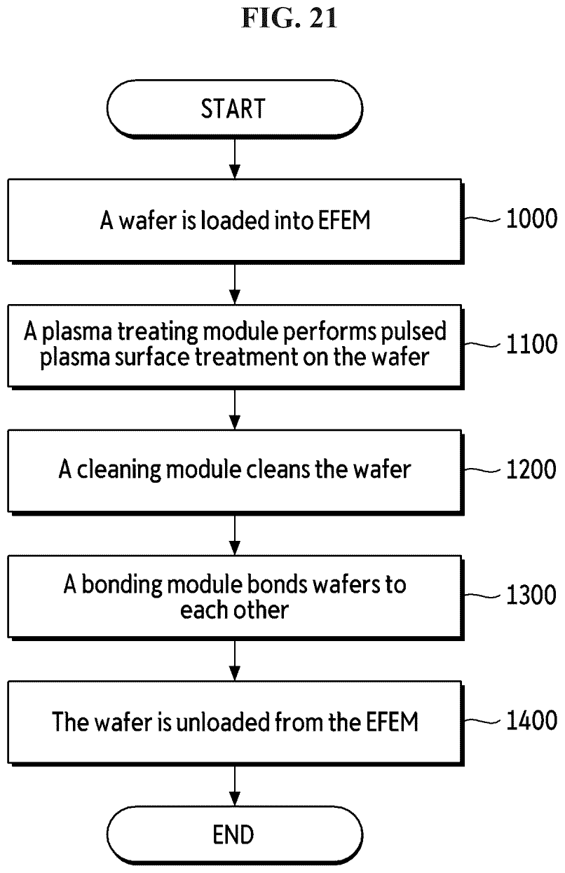

FIG. 21 is a diagram for illustrating a hybrid bonding method according to some embodiments of the present disclosure. For convenience of description, contents duplicate with contend described above with reference to FIGS. 1 to 20 may be briefly described or repeated descriptions thereof may be omitted.

To perform the hybrid bonding method, the hybrid bonding apparatus may be provided, wherein the hybrid bonding apparatus may include the plasma treater 100 that performs pulsed plasma surface treatment, the pulse controller 200 connected to the plasma treater 100 and configured to control on/off of the pulse, the cleaner 300 that cleans the wafer, the bonder 400 for bonding the wafers to each other, and the EFEM 500 for loading/unloading wafers (see FIG. 1).

Referring to FIG. 21, the wafer is loaded into the EFEM in operation 1000.

The wafer 10 (see FIG. 3) may include the bonding pad. In this regard, the wafer 10 may include various semiconductor elements such as dynamic random access memory (DRAM), VNAND, high bandwidth memory (HBM), and a contact image sensor (CIS).

Subsequently, the plasma treater performs pulsed plasma surface treatment on the wafer in the operation 1100.

For example, the wafer 10 may be transferred from the EFEM 500 to the plasma treater 100 using the transfer module. The wafer 10 may be subjected to pulsed plasma surface treatment in the plasma treater 100. When the pulsed plasma surface treatment has been performed on the wafer 10, the influence of the ion bombardment that causes the metal re-sputtering may be minimized.

Next, the cleaner cleans the wafer in operation 1200.

For example, the wafer 10 may be transferred from the plasma treater 100 to the cleaner 300 using the transfer module. The wafer 10 may be cleaned in the cleaner 300.

Next, the bonder bonds a wafer to another wafer in operation 1300.

For example, the wafer 10 may be transferred from the cleaner 300 to the bonder 400 using the transfer module. At this stage, the wafer 10 may be the first wafer 20 (see FIG. 7) or the second wafer 30 (see FIG. 7). The bonder 400 may align the second wafer 30 with the first wafer 20. The bonder 400 may bond the first wafer 20 and the second wafer 30 to each other. The first wafer 20 may include the first insulating film 16 and the first bonding pad 15 embedded in the first insulating film 16, and the second wafer 30 may include the second insulating film 26 and the second bonding pad 25 embedded in the second insulating film 26. The bonder 400 may bond the first bonding pad 15 and the second bonding pad 25 to each other.

The wafer is then unloaded from the EFEM 1400.

For example, the wafer 10, including both the first wafer 20 and the second wafer 30, may be transferred from the bonder 400 to the EFEM 500 using the transfer module. The first wafer 20 and second wafer 30, that are hybrid bonded together, may be transferred to the EFEM 500 and may be unloaded therefrom to the outside.

According to embodiments of the present disclosure, the operation 1000 may be performed with respect to the first wafer 20 and the second wafer 30 at a same time or at different times. The operation 1100 may be performed with respect to the first wafer 20 and the second wafer 30 at a same time or at different times. Also, the operation 1200 may be performed with respect to the first wafer 20 and the second wafer 30 at a same time or at different times. For example, the first wafer 20 and the second wafer 30 may be simultaneously loaded or loaded at different times from each other, simultaneously plasma treated or plasma treated at different times from each other, and/or simultaneously cleaned or cleaned at different times from each other. For example, the first wafer 20 may be cleaned (operation 1200) while the second wafer is plasma treated (operation 1100), but embodiments of the present disclosure are not limited thereto.

According to embodiments of the present disclosure, the hybrid bonding apparatus may further include at least one actuator (e.g., at least one robot) in one or more (e.g., some or all) from among the plasma treater 100, the cleaner 300, the bonder 400, and the bonder 500, and/or between at least two from among the plasma treater 100, the cleaner 300, the bonder 400, and the bonder 500. The at least one actuator may be configured to move wafers (e.g., the first wafer 20 and/or the second wafer 30) within and/or between the various modules described above.

According to embodiments of the present disclosure, the hybrid bonding apparatus may further include a controller. The controller may include at least one processor and memory storing computer instructions. The controller may be configured to cause one or more (e.g., some or all) of the components of the hybrid bonding apparatus to perform their functions. For example, the controller may be configured to cause the hybrid bonding apparatus to perform the hybrid bonding method described above with respect to FIG. 21. The computer instructions may be configured to, when executed by the at least one processor, cause the controller to perform its functions.

Although non-limiting example embodiments of the present disclosure have been described with reference to the accompanying drawings, embodiments of the present disclosure are not limited to the above example embodiments, and may be implemented in various different forms. A person skilled in the art may appreciate that embodiments of the present disclosure may be practiced in other concrete forms without departing from the spirit and scope of the present disclosure. Therefore, it should be appreciated that the example embodiments described above are not restrictive and are illustrative in all respects.

What is claimed is:

1. A hybrid bonding apparatus comprising:
a plasma treater configured to perform a pulsed plasma surface treatment on a first wafer, wherein the first wafer comprises a bonding pad;
a pulse controller connected to the plasma treater and configured to control on/off of a pulse of the pulsed plasma surface treatment;
a cleaner configured to clean the first wafer;
a bonder configured to bond the first wafer and a second wafer to each other; and
an equipment front end module (EFEM) configured to load the first wafer and the second wafer, and unload the first wafer and the second wafer, after being bonded together.

2. The hybrid bonding apparatus of claim 1, wherein the pulse controller is further configured to change an ion energy distribution of pulsed plasma in the pulsed plasma surface treatment by adjusting a pulse frequency and a duty ratio of the pulsed plasma.

3. The hybrid bonding apparatus of claim 1, wherein the plasma treater is further configured to, by performing the pulsed plasma surface treatment, form a passivation film on the bonding pad of the first wafer.

4. The hybrid bonding apparatus of claim 1, wherein the pulse controller is further configured to control on/off of the pulse by controlling on/off of each of a source RF power and a bias RF power.

5. The hybrid bonding apparatus of claim 4, wherein the pulse controller is further configured to control the on/off of the pulse using at least one from among source pulsing, bias pulsing, synchronous pulsing, and asynchronous pulsing.

6. The hybrid bonding apparatus of claim 1, wherein the pulsed plasma surface treatment comprises a pulse-on period and a pulse-off period that the pulse controller is configured to control,
wherein the first wafer comprises an interlayer insulating film on the bonding pad, and
wherein, in the pulse-off period, a passivation film is formed on the bonding pad and the interlayer insulating film.

7. The hybrid bonding apparatus of claim 1, wherein the hybrid bonding apparatus is configured such that:
the first wafer is loaded into the EFEM, and then is transferred to the plasma treater;
the first wafer is subjected to the pulsed plasma surface treatment in the plasma treater, and then is transferred to the cleaner;
the first wafer is cleaned in the cleaner, and then transferred to the bonder;
the first wafer is bonded to the second wafer in the bonder, and then the first wafer and the second wafer, that are bonded together, are transferred to the EFEM; and
the first wafer and the second wafer, that are bonded together, are unloaded from the EFEM.

8. The hybrid bonding apparatus of claim 7, wherein the first wafer comprises a first bonding pad, and the second wafer comprises a second bonding pad,
wherein the bonder is configured to bond the first wafer and the second wafer to each other so that the second bonding pad is on the first bonding pad.

9. The hybrid bonding apparatus of claim 8, wherein each of the first bonding pad and the second bonding pad comprises at least one from among copper, aluminum, tungsten, ruthenium, and molybdenum.

10. A hybrid bonding apparatus comprising:
a plasma treater configured to perform a pulsed plasma surface treatment on a wafer, wherein the wafer comprises first bonding pads;
a pulse controller connected to the plasma treater and configured to control on/off of a pulse of the pulsed plasma surface treatment;
a cleaner configured to clean the wafer;
a bonder configured to bond the wafer and a plurality of dies to each other, wherein the plurality of dies comprise third bonding pads, respectively; and
an equipment front end module (EFEM) configured to load or unload the wafer and the plurality of dies that are bonded to each other,
wherein the bonder is further configured to bond the plurality of dies onto the wafer such that the third bonding pads are connected to the first bonding pads.

11. The hybrid bonding apparatus of claim 10, wherein the hybrid bonding apparatus is configured such that:
the wafer is loaded into the EFEM, and then is transferred to the plasma treater;
the wafer is subjected to the pulsed plasma surface treatment in the plasma treater, and then is transferred to the cleaner;
the wafer is cleaned in the cleaner, and then is transferred to the bonder;
the wafer and the plurality of dies are bonded to each other in the bonder, and then are transferred to the EFEM; and
the wafer and the plurality of dies, that are bonded to each other, are unloaded from the EFEM.

12. The hybrid bonding apparatus of claim 10, wherein the pulse controller is further configured to change an ion energy distribution of pulsed plasma in the pulsed plasma surface treatment by adjusting a pulse frequency and a duty ratio of the pulsed plasma.

13. The hybrid bonding apparatus of claim 10, wherein the plasma treater is further configured to, by performing the pulsed plasma surface treatment, form a passivation film on the first bonding pads of the wafer.

14. The hybrid bonding apparatus of claim 13, wherein the pulsed plasma surface treatment comprises a pulse-on period and a pulse-off period that the pulse controller is configured to control, and
wherein the passivation film is formed in the pulse-off period.

15. The hybrid bonding apparatus of claim 10, wherein the pulse controller is further configured to control on/off of the pulse by controlling on/off of each of a source RF power and a bias RF power.

16. The hybrid bonding apparatus of claim 15, wherein the pulse controller is further configured to control the on/off of the pulse using at least one from among source pulsing, bias pulsing, synchronous pulsing, and asynchronous pulsing.

17. The hybrid bonding apparatus of claim 10, wherein the pulsed plasma surface treatment comprises a pulse-on period and a pulse-off period that the pulse controller is configured to control,
wherein the wafer comprises an interlayer insulating film on the first bonding pads, and
wherein, in the pulse-off period, a passivation film is formed on the first bonding pads and the interlayer insulating film.

18. A hybrid bonding apparatus comprising:
a plasma treater configured to perform a pulsed plasma surface treatment on a first wafer and one from among a second wafer and a plurality of dies, wherein the first wafer comprises a first bonding pad, the second wafer comprises a second bonding pad, and the plurality of dies comprises a third bonding pad;
a pulse controller connected to the plasma treater and configured to control on/off of a pulse of the pulsed plasma surface treatment;
a cleaner configured to clean the first wafer and the one from among the second wafer and the plurality of dies; and
a bonder configured to bond the first wafer and the one from among the second wafer and the plurality of dies to each other; and
an equipment front end module (EFEM) configured to load the first wafer and the one from among the second wafer and the plurality of dies, and unload the first wafer and the one from among the second wafer and the plurality of dies, after being bonded together,
wherein the hybrid bonding apparatus is configured such that the first wafer and the one from among the second wafer and the plurality of dies:
are loaded into the EFEM, and then are transferred to the plasma treater;
are subjected to the pulsed plasma surface treatment in the plasma treater, and then are transferred to the cleaner;
are cleaned in the cleaner, and then are transferred to the bonder;
are bonded to each other in the bonder, and then are transferred to the EFEM; and
are unloaded from the EFEM.

19. The hybrid bonding apparatus of claim 18, wherein the pulse controller is further configured to change ion energy distribution of pulsed plasma in the pulsed plasma surface treatment by adjusting a pulse frequency and a duty ratio of the pulsed plasma.

20. The hybrid bonding apparatus of claim 18, wherein the performing the pulsed plasma surface treatment on the first wafer comprises forming, by the pulsed plasma surface treatment, a passivation layer on the first bonding pad of the first wafer.
